(19) United States
(12) Patent Application Publication
(10) Pub. No.: US 2013/0153868 A1
(43) Pub. Date: Jun. 20, 2013

(54) ORGANIC ELECTROLUMINESCENT APPARATUS

(71) Applicant: Au Optronics Corporation, Hsinchu (TW)

(72) Inventors: Chang-Yen Wu, Taipei City (TW); Meng-Ting Lee, Taipei City (TW); Meng-Huan Ho, Taipei City (TW); Ting-Yi Cho, New Taipei City (TW); Po-Hsuan Chiang, New Taipei City (TW); Chieh-Wei Chen, Taichung City (TW)

(73) Assignee: AU OPTRONICS CORPORATION, Hsinchu (TW)

(21) Appl. No.: 13/692,977

(22) Filed: Dec. 3, 2012

(30) Foreign Application Priority Data
Dec. 19, 2011 (TW) 100147167

(51) Int. Cl. H01L 51/50

(52) U.S. Cl. CPC H01L 51/504
USPC 257/40

(57) ABSTRACT

An organic electroluminescent apparatus including an anode, a cathode, a first organic light emitting unit layer, a plurality of second organic light emitting unit layers, and a plurality of bonding layers is provided. The first organic light emitting unit layer has a phosphorescent host material for emitting blue light. The second organic light emitting unit layers have a host material for emitting light other than blue light. The first organic light emitting unit layer and the second organic light emitting unit layers are located between the anode and the cathode to obtain white light by mixing light. Each of the bonding layers is located between the first organic light emitting unit layer and one of the second organic light emitting unit layers or between two of the second organic light emitting unit layers.

### CROSS-REFERENCE TO RELATED APPLICATION

This application claims the priority benefit of Taiwan application serial no. 100147167, filed on Dec. 19, 2011. The entirety of the above-mentioned patent application is hereby incorporated by reference herein and made a part of this specification.

### BACKGROUND OF THE INVENTION

1. Field of the Invention

The invention relates to a light emitting apparatus. More particularly, the invention relates to an organic electroluminescent apparatus.

2. Description of Related Art

With the development of high technology, video products, especially digital video or image apparatuses, have been widely applied in daily lives, and displays on the digital video or image apparatuses play an important role in displaying relevant information. Users are able to read information from the displays or further control the operation of the apparatuses. In order to comply with the modern life style, the video or image apparatuses tend to be miniaturized. Although the conventional cathode ray tube (CRT) display has advantages, it occupies significant area and consumes power to a great extent. Hence, along with the advance in manufacturing technology of opto-electronics and semiconductors, flat panel displays have been vigorously developed, such as liquid crystal display (LCD) apparatuses or organic electroluminescent display (OLED) apparatuses.

Since the OLED apparatuses are self-illuminating apparatuses, driven by direct-current (DC) low voltages, and characterized by wide view angle, high brightness, high efficiency, high contrast, and compactness, the OLED apparatuses are likely to become mainstream products of the next generation flat panel displays. To feasibly meet the requirement for high resolution, a white light OLED apparatus may be equipped with color filters.

Besides, an OLED apparatus need to have a tandem structure, so as to satisfy the commercialized demands for long service life and high light emitting efficiency. A conventional OLED apparatus with a tandem structure as shown in FIG. 1 is constituted by a cathode 110, an anode 120, organic light emitting unit layers 130 and 140, and a bonding layer 150. The organic light emitting unit layer 130 has a host material for emitting blue light and red light, and the organic light emitting unit layer 140 has a host material for emitting blue light and green light. Thereby, white light may be obtained by mixing the color light. Nonetheless, the operating voltage of the host material for emitting blue light is apparently greater than the operating voltage of the host material for emitting red light or green light. As the organic light emitting unit layers 130 and 140 both have the host material for emitting blue light, the operating voltage of the entire OLED apparatus with the tandem structure significantly increases, thus reducing the overall power efficiency to a great extent.

### SUMMARY OF THE INVENTION

The invention provides an organic electroluminescent apparatus capable of resolving issues of the overly high operating voltage and the excessively low power efficiency of a conventional organic electroluminescent apparatus.

In the invention, an organic electroluminescent apparatus including an anode, a cathode, a first organic light emitting unit layer, a plurality of second organic light emitting unit layers, and a plurality of bonding layers is provided. The first organic light emitting unit layer has a phosphorescent host material for emitting blue light. The second organic light emitting unit layers have a host material for emitting light other than blue light. The first organic light emitting unit layer and the second organic light emitting unit layers are located between the anode and the cathode to obtain white light by mixing light. One of the bonding layers is located between the first organic light emitting unit layer and one of the second organic light emitting unit layers, each of another bonding layers is located between two of the second organic light emitting unit layers.

According to an embodiment of the invention, one of the second organic light emitting unit layers has a host material for emitting red light and green light. The host material of the one of the second organic light emitting unit layers for emitting the red light and the green light may be a fluorescent material or a phosphorescent material.

According to an embodiment of the invention, one of the second organic light emitting unit layers has a host material for emitting red light or green light.

According to an embodiment of the invention, the first organic light emitting unit layer further has a host material for emitting red light or green light. The host material of the first organic light emitting unit layer for emitting the red light or the green light may be a fluorescent material or a phosphorescent material.

According to an embodiment of the invention, each of the bonding layers includes an electron transporting layer, a charge connecting layer, and a hole transporting layer. The hole transporting layer is located between the charge connecting layer and the cathode, and the charge connecting layer is located between the electron transporting layer and the hole transporting layer.

According to an embodiment of the invention, the organic electroluminescent apparatus further includes an electron transporting layer located between the cathode and one of the first organic light emitting unit layer and the second organic light emitting unit layers which is closest to the cathode.

According to an embodiment of the invention, the organic electroluminescent apparatus further includes an electron transporting layer located between the anode and one of the first organic light emitting unit layer and the second organic light emitting unit layers which is closest to the anode.

According to an embodiment of the invention, the second organic light emitting unit layers include at least two layers both having the host material for emitting the red light and the green light.

According to an embodiment of the invention, the second organic light emitting unit layers include two layers, one of the two layers has the host material for emitting the red light, and the other layer has the host material for emitting the green light.

Based on the above, in the organic electroluminescent apparatus of the invention, only one of the organic light emitting unit layers has the phosphorescent host material for emitting the blue light; thereby, the operating voltage can be reduced, and the power efficiency can be improved.

In order to make the aforementioned and other features and advantages of the invention more comprehensible, embodiments accompanying figures are described in detail below.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the invention.

FIG. 1 is a schematic view illustrating a conventional organic electroluminescent apparatus.

FIG. 2 is a schematic view illustrating an organic electroluminescent apparatus according to an embodiment of the invention.

FIG. 3 is a schematic view illustrating an organic electroluminescent apparatus according to another embodiment of the invention.

FIG. 4 and FIG. 5 are schematic views illustrating an organic electroluminescent apparatus according to other two embodiments of the invention.

FIG. 6 is a schematic view illustrating an organic electroluminescent apparatus according to another embodiment of the invention.

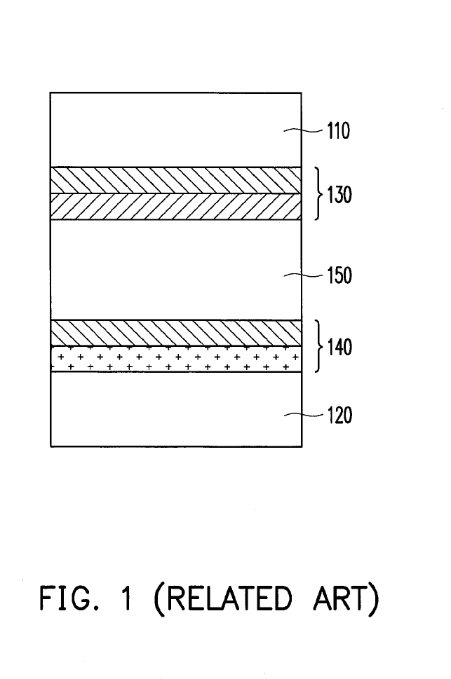

### DESCRIPTION OF EMBODIMENTS

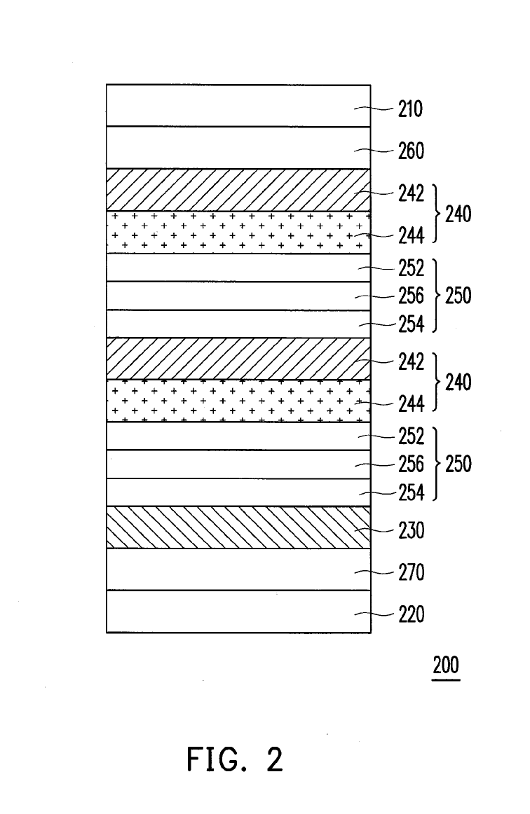

FIG. 2 is a schematic view illustrating an organic electroluminescent apparatus according to an embodiment of the invention. With reference to FIG. 2, the organic electroluminescent apparatus 200 described in the present embodiment includes an anode 210, a cathode 220, an organic light emitting unit layer 230, a plurality of organic light emitting unit layers 240, and a plurality of bonding layers 250. The organic light emitting unit layer 230 has a phosphorescent host material for emitting blue light. In the present embodiment, the phosphorescent host material for emitting blue light is one of the following compounds, for instance:

N,N′-dicarbazolyl-3,5-benzene(mCP)

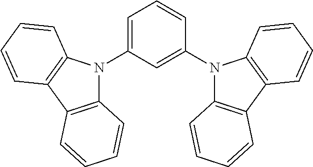 [SMILES: c1cc(-n2c3ccccc3c3ccccc32)cc(-n2c3ccccc3c3ccccc32)c1]

2,6-bis(3-(9H-carbazol-9-yl)phenyl)pyridine(26DCzPPy)

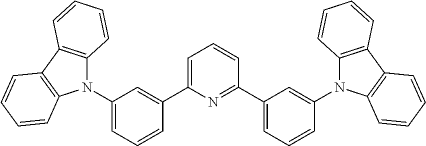 [SMILES: c1cc(-c2cccc(-c3cccc(-n4c5ccccc5c5ccccc54)c3)n2)cc(-n2c3ccccc3c3ccccc32)c1]

2,8-bis(diphenylphosphoryl)dibenzothiophene(PO15)

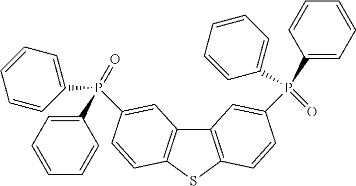

The organic light emitting unit layer 230 and the organic light emitting unit layers 240 are located between the anode 210 and the cathode 220 to obtain white light by mixing light. Each of the bonding layers 250 is located between the organic light emitting unit layer 230 and one of the organic light emitting unit layers 240 or between two of the organic light emitting unit layers 240.

The quantum efficiency of the phosphorescent host material is four times the quantum efficiency of the fluorescent host material, and therefore the power efficiency of the organic light emitting unit layer 230 is greater than that of the fluorescent host material. Thereby, the organic electroluminescent apparatus 200 described herein has favorable power efficiency. From another perspective, the organic electroluminescent apparatus 200 merely has one organic light emitting unit layer emitting blue light; hence, the operating voltage of the organic electroluminescent apparatus 200 can be reduced.

In the present embodiment, both of the organic light emitting unit layers 240 have the host materials 242 and 244 for emitting red light and green light, respectively. The light emitted from the organic light emitting unit layer 230 and the two organic light emitting unit layers 240 can be mixed to generate white light. It should be mentioned that the order of arranging the organic light emitting unit layer 230 and the two organic light emitting unit layers 240 between the anode 210 and the cathode 220 is not limited herein. Additionally, it is not necessary for the two organic light emitting unit layers 240 to emit light with identical color, i.e., the two organic light emitting unit layers 240 may respectively emit light with different colors, and the color light is not limited to the red light and the green light as long as the light emitted from the organic light emitting unit layers 240 may be mixed with the blue light emitted from the organic light emitting unit layer 230 to generate white light. In the present embodiment, the host materials 242 and 244 of the organic light emitting unit layers 240 for emitting the red light and the green light may be fluorescent materials or phosphorescent materials.

Each of the bonding layers 250 in the present embodiment includes an electron transporting layer 252, a charge connecting layer 256, and a hole transporting layer 254. The hole transporting layer 254 is located between the charge connecting layer 256 and the cathode 220, and the charge connecting layer 256 is located between the electron transporting layer 252 and the hole transporting layer 254. According to the present embodiment, the organic electroluminescent apparatus 200 further includes a hole transporting layer 260 and an electron transporting layer 270. The hole transporting layer 260 is located between the organic light emitting unit layer 230 and the anode 210. However, when the organic light emitting unit layer closest to the anode 210 is the organic light emitting unit layer 240, the hole transporting layer 260 is located between the anode 210 and the organic light emitting unit layer 240 closest to the anode 210. The electron transporting layer 270 is located between the organic light emitting unit layer 240 and the cathode 220. Nonetheless, when the organic light emitting unit layer closest to the cathode 220 is the organic light emitting unit layer 230, the electron transporting layer 270 is located between the cathode 220 and the organic light emitting unit layer 230. The hole transporting layer and the electron transporting layer are conducive to improvement of the power efficiency of the organic electroluminescent apparatus 200.

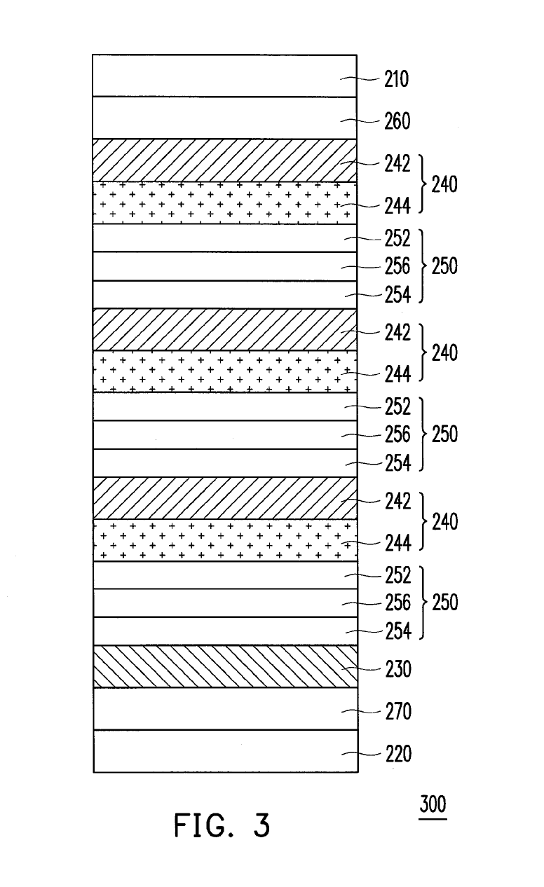

FIG. 3 is a schematic view illustrating an organic electroluminescent apparatus according to another embodiment of the invention. With reference to FIG. 3, the organic electroluminescent apparatus 300 described in the present embodiment is similar to the organic electroluminescent apparatus 200 depicted in FIG. 2, while the difference therebetween lies in that the organic electroluminescent apparatus 300 has one more organic light emitting unit layer 240. All of the organic light emitting unit layers 240 in the present embodiment have host materials 242 and 244 for emitting red light and green light. Note that it is not necessary for the organic light emitting unit layers 240 to emit light with identical color, i.e., the organic light emitting unit layers 240 may respectively emit light with different colors, and the color light is not limited to the red light and the green light as long as the light emitted from the organic light emitting unit layers 240 may be mixed with the blue light emitted from the organic light emitting unit layer 230 to generate white light.

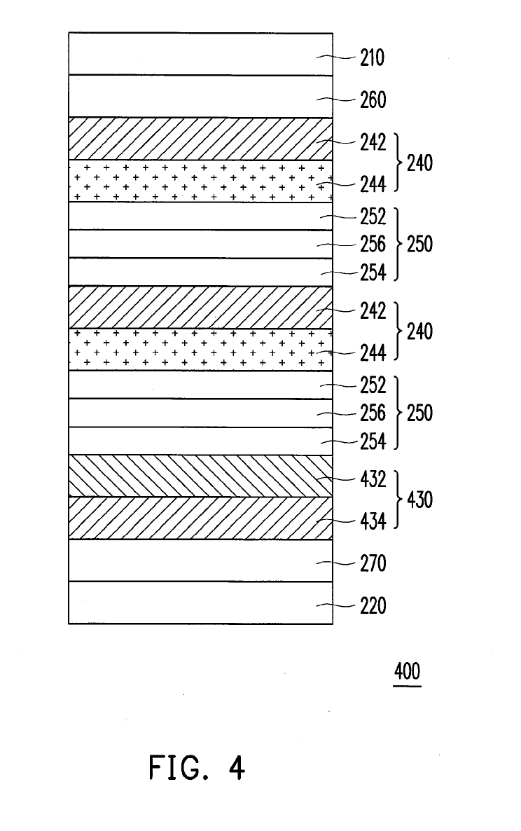

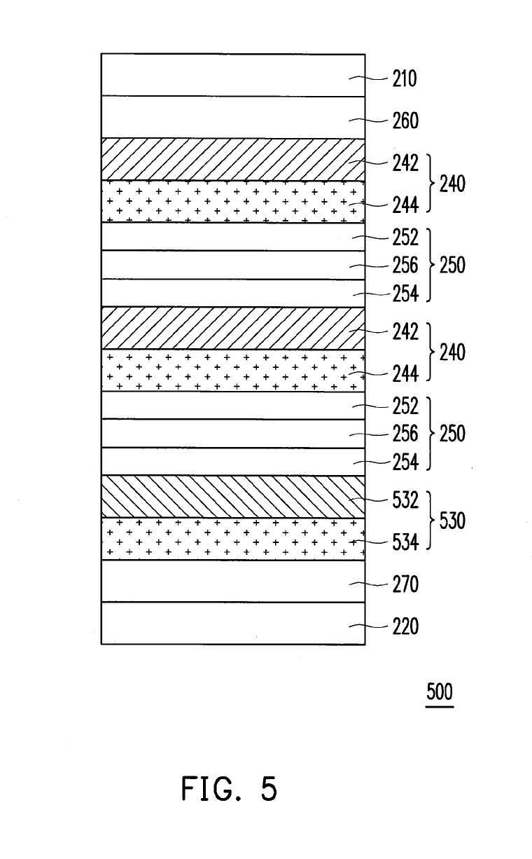

FIG. 4 and FIG. 5 are schematic views illustrating an organic electroluminescent apparatus according to other two embodiments of the invention. With reference to FIG. 4 and FIG. 5, the organic electroluminescent apparatuses 400 and 500 described herein are similar to the organic electroluminescent apparatus 200 depicted in FIG. 2, while the difference lies in that the organic light emitting unit layer 430 in FIG. 4 has a host material 432 for emitting blue light and a host material 434 for emitting red light, and the organic light emitting unit layer 530 in FIG. 5 has a host material 532 for emitting blue light and a host material 534 for emitting green light. However, both the organic electroluminescent apparatus 400 and the organic electroluminescent apparatus 500 are still equipped with only one organic light emitting unit layer having the phosphorescent host material for emitting blue light. The host material 434 for emitting the red light and the host material 534 for emitting the green light may be fluorescent materials or phosphorescent materials.

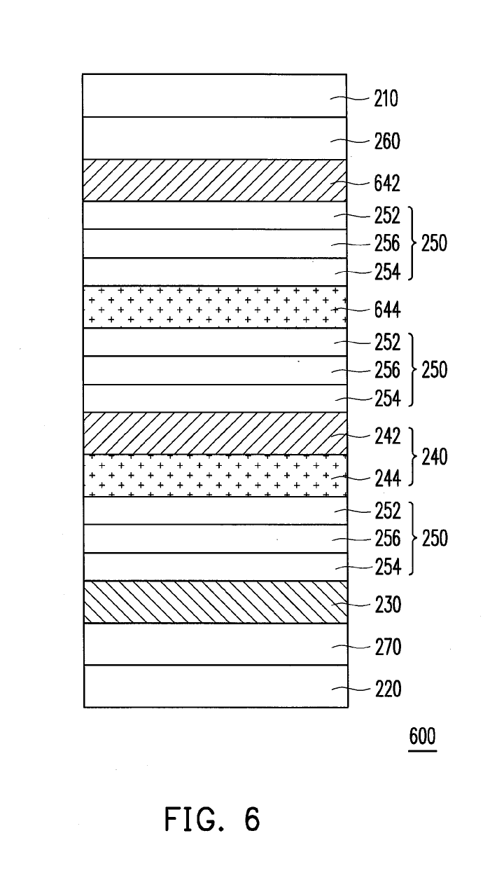

FIG. 6 is a schematic view illustrating an organic electroluminescent apparatus according to another embodiment of the invention. With reference to FIG. 6, the organic electroluminescent apparatus 600 described herein is similar to the organic electroluminescent apparatus 300 depicted in FIG. 3. The organic light emitting unit layers 230 and 240 in FIG. 6 are the same as those in FIG. 3. Nonetheless, the organic electroluminescent apparatus 600 further has organic light emitting unit layers 642 and 644, in which the organic light emitting unit layer 642 merely has a host material for emitting red light, and the organic light emitting unit layer 644 merely has a host material for emitting green light. Note that the organic electroluminescent apparatus 600 is also equipped with only one organic light emitting unit layer 230 having the phosphorescent host material for emitting blue light. The host materials of the organic light emitting unit layers 240, 642, and 644 for emitting the red light and the green light may be fluorescent materials or phosphorescent materials.

To sum up, in the organic electroluminescent apparatus of the invention, only one of the organic light emitting unit layers has the host material for emitting the blue light; thereby, the operating voltage of the organic electroluminescent apparatus can be reduced. Moreover, since the host material for emitting the blue light in the organic electroluminescent apparatus of the invention is the phosphorescent material, the power efficiency of the organic electroluminescent apparatus can be improved.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. An organic electroluminescent apparatus comprising:
an anode;
a cathode;
a first organic light emitting unit layer having a phosphorescent host material for emitting blue light;
a plurality of second organic light emitting unit layers having a host material for emitting light other than blue light, wherein the first organic light emitting unit layer and the second organic light emitting unit layers are located between the anode and the cathode to obtain white light by mixing light; and
a plurality of bonding layers, each of the bonding layers being located between the first organic light emitting unit layer and one of the second organic light emitting unit layers or between two of the second organic light emitting unit layers.

2. The organic electroluminescent apparatus as recited in claim 1, wherein one of the second organic light emitting unit layers has a host material for emitting red light and green light.

3. The organic electroluminescent apparatus as recited in claim 2, wherein the host material of the one of the second organic light emitting unit layers for emitting the red light and the green light is a fluorescent material or a phosphorescent material.

4. The organic electroluminescent apparatus as recited in claim 2, wherein another one of the second organic light emitting unit layers has a host material for emitting red light or green light.

5. The organic electroluminescent apparatus as recited in claim 4, wherein the host material of the another one of the second organic light emitting unit layers for emitting the red light or the green light is a fluorescent material or a phosphorescent material.

6. The organic electroluminescent apparatus as recited in claim 1, wherein the first organic light emitting unit layer further has a host material for emitting red light or green light.

7. The organic electroluminescent apparatus as recited in claim 6, wherein the host material of the first organic light emitting unit layer for emitting the red light or the green light is a fluorescent material or a phosphorescent material.

8. The organic electroluminescent apparatus as recited in claim 1, wherein each of the bonding layers comprises:
an electron transporting layer;
a charge connecting layer; and
a hole transporting layer located between the charge connecting layer and the cathode, wherein the charge connecting layer is located between the electron transporting layer and the hole transporting layer.

9. The organic electroluminescent apparatus as recited in claim 1, further comprising an electron transporting layer located between the cathode and one of the second organic light emitting unit layers closest to the cathode.

10. The organic electroluminescent apparatus as recited in claim 1, further comprising a hole transporting layer located between the first organic light emitting unit layer and the anode.

11. The organic electroluminescent apparatus as recited in claim 2, wherein the second organic light emitting unit layers comprise at least two layers both having the host material for emitting the red light and the green light.

12. The organic electroluminescent apparatus as recited in claim 4, wherein the second organic light emitting unit layers comprise two layers, one of the two layers has the host material for emitting the red light, and the other layer has the host material for emitting the green light.
